(19) United States
(12) Patent Application Publication
(10) Pub. No.: US 2009/0073780 A1
(43) Pub. Date: Mar. 19, 2009

(54) Memory device for detecting bit line leakage current and method thereof

(75) Inventor: Chang-sik Kim, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/216,400

(22) Filed: Jul. 3, 2008

(30) Foreign Application Priority Data
Jul. 4, 2007 (KR) 10-2007-0067145

(51) Int. Cl. G11C 7/00; G11C 5/14

(52) U.S. Cl. 365/189.07; 365/226

(57) ABSTRACT

A memory device may include a plurality of bit line pairs, at least one local data line pair, and/or a bit line leakage current measurement unit. The at least one local data line pair may be connected to the bit line pairs in response to a column selection signal. The bit line leakage current measurement unit may be configured to monitor a direct drain quiescent current (IDDQ) flowing though at least one measurement line connected to the at least one local data line pair in response to a test mode signal.

### PRIORITY STATEMENT

This application claims the benefit of priority to Korean Patent Application No. 10-2007-0067145, filed on Jul. 4, 2007, in the Korean Intellectual Property Office, the entire contents of which are incorporated herein in their entirety by reference.

### BACKGROUND

1. Field

Example embodiments relate to a semiconductor memory device, and for example, to a memory device for detecting a bit line leakage current and/or a method thereof.

2. Description of Related Art

More highly integrated semiconductor memory devices and an increased demand for reliability place more attention on the testing of fabricated semiconductor devices. Semiconductor memory devices that have been fabricated according to sub-micron design rules may suffer from new failures that are not modeled by existing stuck-at faults. Because most of the new failures are not logic faults, but bridging or open faults, detection of the new failures using a voltage testing method is ineffective.

A more highly integrated semiconductor device may include tens of thousands of arranged bit lines. A leakage current may be generated in a path between a bit line and a word line or a path between bit lines. Therefore, if the leakage current of every bit line is measured using a parametric (or precision) measurement unit (PMU) of a tester, testing of only a single semiconductor device would take several hours to complete.

### SUMMARY

Example embodiments provide a memory device for detecting a bit line leakage current using a direct drain quiescent current (IDDQ).

According to an example embodiment, a memory device may include a plurality of bit line pairs, at least one local data line pair, and/or a bit line leakage current measurement unit. The at least one local data line pair may be connected to the bit line pairs in response to a column selection signal. The bit line leakage current measurement unit may be configured to monitor a direct drain quiescent current (IDDQ) flowing though at least one measurement line connected to the at least one local data line pair in response to a test mode signal.

According to an example embodiment, the bit line leakage current measurement unit may include a first switch, a second switch, a resistor, and/or a measurement pad. The first switch may be configured to connect the at least one local data line pair with a first measurement line, the at least one measurement line including the first measurement line and a second measurement line. The second switch may be configured to connect the first measurement line with the second measurement line in response to the test mode signal. The resistor may be connected between a power supply voltage and the second measurement line. The measurement pad may be connected to the second measurement line.

According to an example embodiment, the first switch may include a first PMOS transistor and/or a second PMOS transistor. The first PMOS transistor may be connected between a local data line of the at least one local data line pair and the first measurement line, the first PMOS transistor having a gate connected to a ground voltage. The second PMOS transistor may be connected between a complementary local data line of the at least one local data line pair and the first measurement line, the second PMOS transistor having a gate connected to the ground voltage.

According to an example embodiment, the resistor may be mounted outside the memory device.

According to an example embodiment, the bit line leakage current measurement unit may include a first switch, a second switch, a resistor, a comparator, and/or a measurement pad. The first switch may be configured to connect the at least one local data line pair with a first measurement line, the at least one measurement line including the first measurement line and a second measurement line. The second switch may be configured to connect the first measurement line with the second measurement line in response to the test mode signal. The resistor may be connected between a power supply voltage and the second measurement line. The comparator may be configured to compare a voltage level of the second measurement line with a reference voltage level. The measurement pad may be connected to an output terminal of the comparator.

According to an example embodiment, the first switch may include a first PMOS transistor and/or a second PMOS transistor. The first PMOS transistor may be connected between a local data line of the at least one local data line pair and the first measurement line, the first PMOS transistor having a gate connected to a ground voltage. The second PMOS transistor may be connected between a complementary local data line of the at least one local data line pair and the first measurement line, the second PMOS transistor having a gate connected to the ground voltage.

According to an example embodiment, the resistor may be mounted outside the memory device.

According to an example embodiment, the memory device may include at least two load transistors configured to supply current to the at least one local data line pair in response to the test mode signal.

According to an example embodiment, the bit line leakage current measurement unit may include a switch, a resistor, and/or a measurement pad. The switch may be configured to connect the at least one local data line pair with the measurement line in response to the test mode signal. The resistor may be connected between a power supply voltage and the measurement line. The measurement pad may be connected to the measurement line.

According to an example embodiment, the switch may include a first PMOS transistor and/or a second PMOS transistor. The first PMOS transistor may be connected between a local data line of the at least one local data line pair and the measurement line, the first PMOS transistor having a gate configured to receive the test mode signal. The second PMOS transistor may be connected between a complementary data line of the at least one local data line pair and the measurement line, the second PMOS transistor having a gate configured to receive the test mode signal.

According to an example embodiment, the resistor may be mounted outside the memory device.

According to an example embodiment, the bit line leakage current measurement unit may include a switch, a resistor, a comparator, and/or a measurement pad. The switch may be configured to connect the at least one local data line pair with the measurement line in response to the test mode signal. The resistor may be connected between a power supply voltage and the measurement line. The comparator may be configured to compare a voltage level of the measurement line with a reference voltage level. The measurement pad may be connected to an output terminal of the comparator.

According to an example embodiment, the switch may include a first PMOS transistor and/or a second PMOS transistor. The first PMOS transistor connected between a local data line of the at least one local data line pair and the measurement line, the first PMOS transistor having a gate configured to receive the test mode signal. The second PMOS transistor may be connected between a complementary data line of the at least one local data line pair and the measurement line, the second PMOS transistor having a gate configured to receive the test mode signal.

According to an example embodiment, the resistor may be mounted outside the memory device.

According to an example embodiment, the memory device may include a pulse width adjustment circuit configured to adjust an enabling period of the column selection signal.

According to an example embodiment, the pulse width adjustment circuit may increase the enabling period of the column selection signal in response to the test mode signal.

According to an example embodiment, a method may include connecting at least one local data line pair to a plurality of bit line pairs in response to a column selection signal. A direct drain quiescent current (IDDQ) flowing through a measurement line connected to the at least one local data line pair may be monitored in response to a test mode signal.

### BRIEF DESCRIPTION OF THE DRAWINGS

The above and/or other aspects and advantages will become more apparent and more readily appreciated from the following detailed description of example embodiments taken in conjunction with the accompanying drawings of which:

FIG. 1 illustrates a memory device according to an example embodiment;

FIG. 2 illustrates a memory device according to another example embodiment;

FIG. 3 illustrates a memory device according to another example embodiment; and

FIG. 4 illustrates a memory device according to another example embodiment.

### DETAILED DESCRIPTION OF EXAMPLE EMBODIMENTS

Example embodiments will now be described more fully hereinafter with reference to the accompanying drawings. Embodiments may, however, be in many different forms and should not be construed as being limited to the example embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when a component is referred to as being “on,” “connected to” or “coupled to” another component, it can be directly on, connected to or coupled to the other component or intervening components may be present. In contrast, when a component is referred to as being “directly on,” “directly connected to” or “directly coupled to” another component, there are no intervening components present. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiments.

Spatially relative terms, such as “beneath,” “below,” “lower,” “above,” “upper” and the like, may be used herein for ease of description to describe one component or feature's relationship to another component(s) or feature(s) as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, and/or components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Reference will now be made to example embodiments, which are illustrated in the accompanying drawings, wherein like reference numerals refer to the like components throughout.

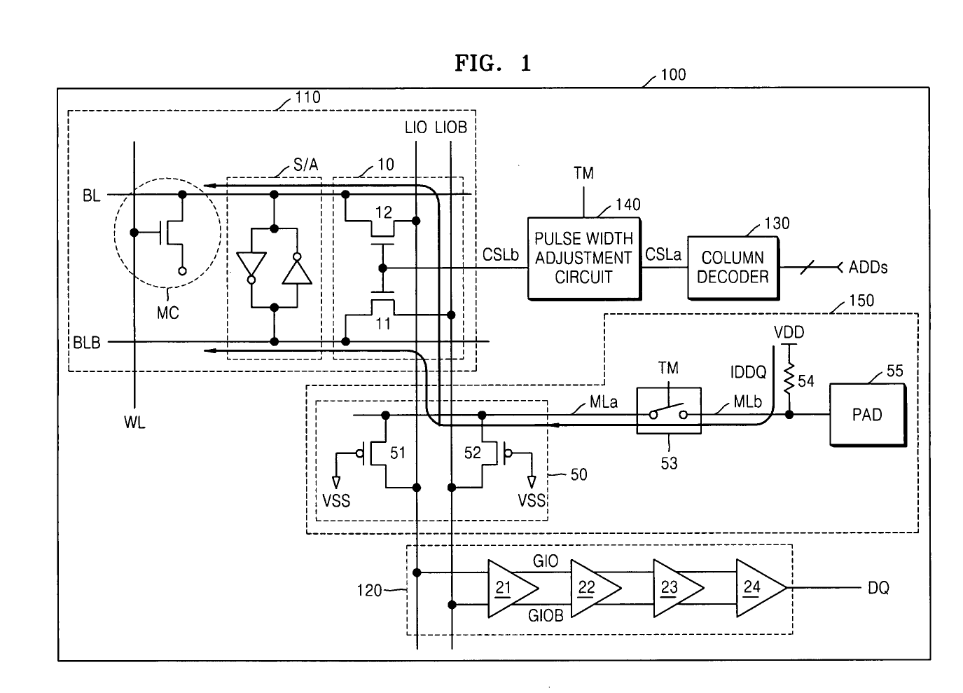

FIG. 1 illustrates a memory device 100 according to an example embodiment.

Referring to FIG. 1, the memory device 100 may include a memory cell array block 110, a data output path 120, a column decoder 130, a pulse width adjustment circuit 140, and/or a bit line leakage current measurement unit 150.

The memory cell array block 110 may include memory cells MC arranged at an intersection between a word line WL and a bit line BL. The memory cell array block 110 may include a plurality of word lines WL and a plurality of bit lines BL, and a plurality of memory cells MC may be arranged at intersections between the word lines WL and the bit lines BL. For brevity, only a single word line WL and a pair of bit lines BL and BLB included in the memory cell array block 110 will now be described. Data stored in the memory cell MC may be sensed and amplified by sense amplifiers S/A and transmitted to the pair of bit lines BL and BLB connected to the sense amplifiers S/A. The sensed and amplified data may be transmitted from the pair of bit lines BL and BLB through a column selection circuit 10 to a pair of local data lines LIO and LIOB. The column selection circuit 10 may include transistors 11 and 12, which connect the pair of bit lines BL and BLB with the local data lines LIO and LIOB in response to a second column selection signal CSLb.

The data output path 120 may include circuit blocks 21, 22, 23, and/or 24, which amplify and buffer data transmitted from the pair of local data lines LIO and LIOB to a pair of global data lines GIO and GIOB, and generate a data output signal DQ.

The column decoder 130 may decode externally received address signals ADDs and generate a first column selection signal CSLa to select the bit line BL. The pulse width adjustment circuit 140 may adjust the pulse width of the first column selection signal CSLa in response to a test mode signal TM and generate the second column selection signal CSLb. The test mode signal TM may be a signal for instructing the bit line leakage current measurement unit 150 to measure the leakage current of the bit line BL. The pulse width adjustment circuit 140 may generate the second column selection signal CSLb in response to the enabling of the test mode signal TM such that an enabling period of the second column selection signal CSLb is longer than an enabling period of the first column selection signal CSLa.

The bit line leakage current measurement unit 150 may include a first switch 50, a second switch 53, a resistor 54, and/or a measurement pad 55. The first switch 50 may include a first PMOS transistor 51 and/or a second PMOS transistor 52. The first PMOS transistor 51 may be connected between the local data line LIO and a first measurement line MLa. The second PMOS transistor 52 may be connected between a complementary local data line LIOB and the first measurement line MLa. Gates of the first and second PMOS transistors 51 and 52 may be connected to a ground voltage VSS and turned on. The second switch 53 may connect the first measurement line MLa with a second measurement line MLb in response to the test mode signal TM. The resistor 54 may be connected between a power supply voltage VDD and the second measurement line MLb, and/or the second measurement line MLb may be connected to a measurement pad 55. Although FIG. 1 illustrates an example embodiment where the resistor 54 is included in the memory device 100, example embodiments are not limited thereto and the resistor 54 may be mounted on an external test apparatus outside the semiconductor device 100.

If the memory device 100 enters a test mode to measure the leakage current of the bit lines BL and BLB, the word line WL may be disabled. The second column selection signal CSLb may be generated, with the longer enabling period, in response to the enabling of the test mode signal TM. The pair of bit lines BL and BLB may be selected and connected to the pair of local data lines LIO and LIOB in response to the second column selection signal CSLb. The pair of local data lines LIO and LIOB may be connected to the first measurement line MLa by the first switch 50, and/or the first measurement line MLa may be connected to the second measurement line MLb by the second switch 53. Accordingly, the power supply voltage VDD, the resistor 54, the first and second measurement lines MLa and MLb, the pair of local data lines LIO and LIOB, and/or the pair of bit lines BL and BLB may form a current path. A direct drain quiescent current (IDDQ) may flow through the current path. The IDDQ current may vary with the leakage current of the bit lines BL and BLB. A voltage drop may occur at both ends of the resistor 54 according to the IDDQ current and affect a voltage level of the measurement pad 55. Therefore, a defect caused by a leakage current may be detected by monitoring the voltage level of the measurement pad 55.

If the memory device 100 enters a normal read mode, the second switch 53 may turned off. Therefore, the word line WL may be enabled, and data stored in the memory cell MC may be sensed and amplified by the sense amplifier S/A and transmitted to the pair of bit lines. BL and BLB. The pair of bit lines BL and BLB may be selected in response to the second column selection signal CLSb having the longer enabling period. Therefore, the sensed and amplified data may be transmitted from the selected bit lines BL and BLB through the pair of local data lines LIO and LIOB and the pair of global data lines GIO and GIOB to the data output path 120, and/or the data output path 120 may generate a data output signal DQ.

The memory device 100 may be designed such that the second column selection signal CSLb selects a plurality of pairs of bit lines BL and BLB which are transmitted to each of a plurality of pairs of local data lines LIO and LIOB. In order to measure the leakage current of the pairs of bit lines BL and BLB selected in response to the second column selection signal CSLb, the second switch 53 may be set to connect the first and second measurement lines MLa and MLb in response to a signal for selecting the pairs of local data lines LIO and LIOB connected to the selected bit lines BL and BLB and the test mode signal TM. Therefore, a voltage drop may occur at both ends of the resistor 54 according to the IDDQ current caused by the leakage current of the bit lines BL and BLB. Accordingly, by monitoring the voltage level of the measurement pad 55 affected by the voltage drop, a defect caused by the leakage current of the bit lines BL and BLB may be detected.

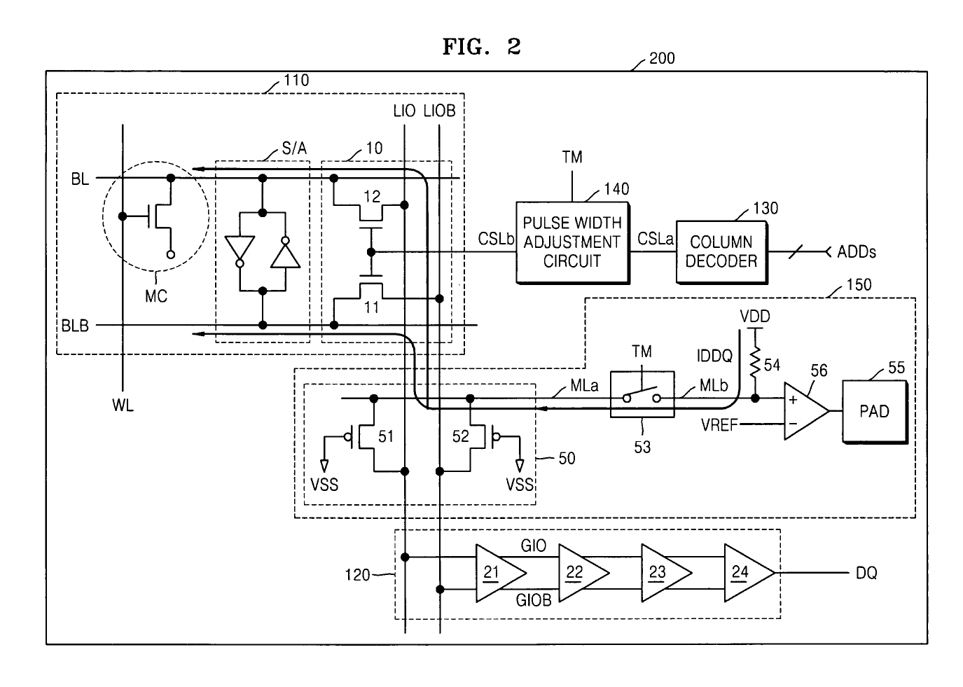

FIG. 2 illustrates a memory device 200 according to another example embodiment.

Referring to FIG. 2, the memory device 200 may have generally the same construction as the memory device 100 shown in FIG. 1 except that the bit line leakage current measurement unit 150 of the memory device 200 may include a comparator 56. The comparator 56 may compare a voltage level of the second measurement line MLb with a reference voltage VREF level, and/or an output of the comparator 56 may be transmitted to the measurement pad 55. The memory device 200 may monitor a logic level of the measurement pad 55 to thereby detect a defect caused by a bit line leakage current.

If the memory device 200 enters a test mode, the comparator 56 may compare the voltage level of the second measurement line MLb, which is affected by an IDDQ current due to the bit line leakage current, with the reference voltage VREF level. If the second measurement line MLb is at a lower voltage level than the reference voltage VREF, the comparator 56 may output a logic low output signal to the measurement pad 55. If the measurement pad 55 is at a logic low level, a defect caused by the bit line leakage current may be detected. In contrast, if the second measurement line MLb is at a higher level than the reference voltage VREF, the comparator 56 may output a logic high output signal to the measurement pad 55. If the measurement pad 55 is at a logic high level, a defect caused by the bit line leakage current may not be detected.

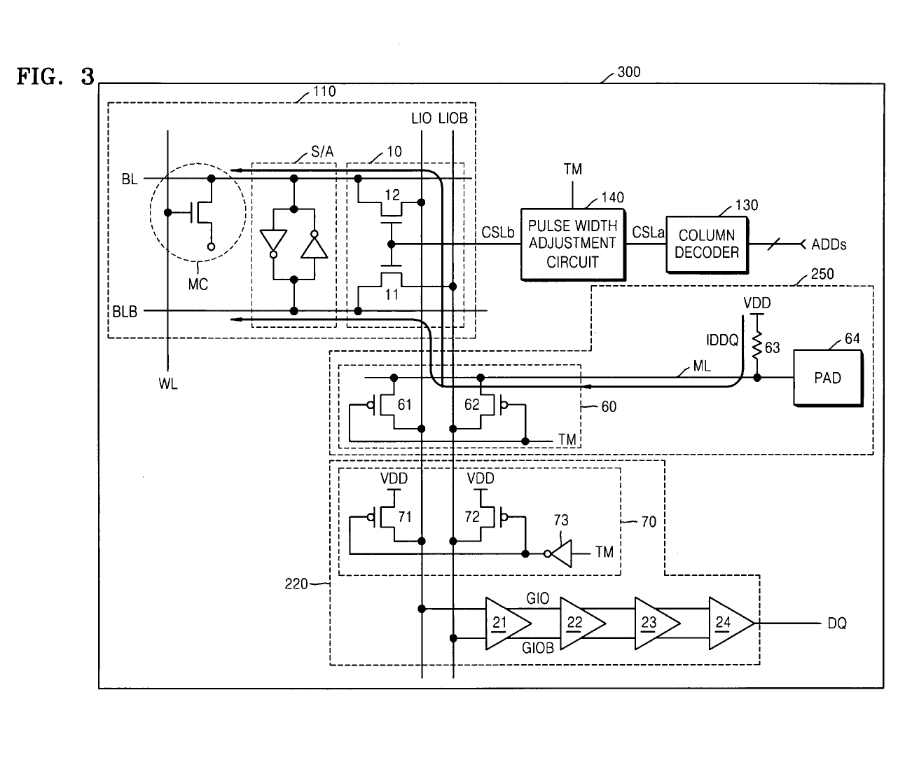

FIG. 3 illustrates a memory device 300 according to another example embodiment.

Referring to FIG. 3, the memory device 300 may have generally the same construction as the memory device 100 shown in FIG. 1 except for a data output path 220 and a bit line leakage current measurement unit 250 may be different from the data output path 120 and the bit line leakage current measurement unit 150 of FIG. 1.

The bit line leakage current measurement unit 250 may include a switch 60, a resistor 63, and/or a measurement pad 64. The switch 60 may include a first PMOS transistor 61 and/or a second PMOS transistor 62. The first PMOS transistor 61 may be connected between the local data line LIO and a measurement line ML. The second PMOS transistor 62 may be connected between the complementary local data line LIOB and the measurement line ML. The first and second PMOS transistors 61 and 62 may be turned on and off in response to the test mode signal TM. The switch 60 may connect the pair of local data lines LIO and LIOB with the measurement line ML in response to the enabling of the test mode signal TM. The resistor 63 may be connected between the power supply voltage VDD and the measurement line ML, and/or the measurement line ML may be connected to the measurement pad 64. Although an example embodiment illustrates in FIG. 3 shows the resistor 63 is included in the memory device 300, example embodiments are not limited thereto and the resistor 63 may be mounted on an external test apparatus outside the memory device 300.

If a first circuit block 21 of circuit blocks 21, 22, 23, and/or 24 that amplify and buffer data of the pair of local data lines LIO and LIOB includes a current sense amplifier, the data output path 220 may control a load transistor unit 70 configured to supply current to the pair of local data lines LIO and LIOB. The load transistor unit 70 may include a first load transistor 71 and/or a second load transistor 72. The first load transistor 71 may be connected between the power supply voltage VDD and the local data line LIO, and/or the second load transistor 72 may be connected between the power supply voltage VDD and the complementary local data line LIOB. The first and second load transistors 71 and 72 may be turned on and off in response to an output signal of an inverter 73 that inverts the test mode signal TM. The load transistor unit 70 may supply current to the pair of local data lines LIO and LIOB in response to the disabling of the test mode signal TM and/or cut off the supply of current to the pair of local data lines LIO and LIOB in response to the enabling of the test mode signal TM.

If the semiconductor device 300 enters a test mode, a word line WL may be disabled, a second column selection signal CSLb, which has a longer enabling period, may be generated in response to the enabling of the test mode signal TM, and/or a pair of bit lines BL and BLB may be selected in response to the second column selection signal CSLb and connected to the pair of local data lines LIO and LIOB. The pair of local data lines LIO and LIOB may be connected to the measurement line ML by the switch 60. The load transistor unit 70 may turn off the first and second load transistors 71 and 72 to thereby cut off the supply of current to the pair of local data lines LIO and LIOB. Therefore, the power supply voltage VDD, the resistor 63, the measurement line ML, the pair of local data lines LIO and LIOB, and/or the pair of bit lines BL and BLB may form a current path. An IDDQ current, which flows through the current path, may vary with the leakage current of the bit lines BL and BLB. A voltage drop may occur at both ends of the resistor 63 according to the IDDQ current and affect a voltage level of the measurement pad 64. Accordingly, a defect caused by the leakage current may be detected by monitoring the voltage level of the measurement pad 64.

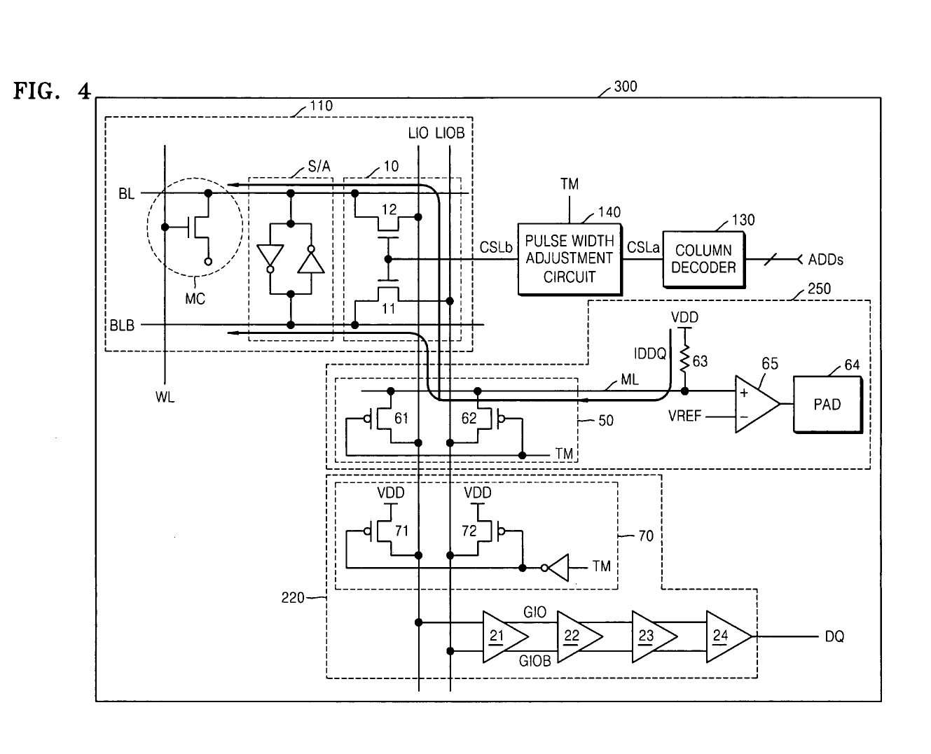

FIG. 4 illustrates a memory device 400 according to another example embodiment.

Referring to FIG. 4, the memory device 400 may have generally the same construction as the memory device 300 shown in FIG. 3 except that the bit line leakage current measurement unit 250 may include a comparator 65. The comparator 65 may compare a voltage level of a measurement line with a reference voltage VREF level and output an output signal to the measurement pad 64. The memory device 400 may monitor a logic level of the measurement pad 64 and detect a defect caused by a bit line leakage current.

If the memory device 400 enters a test mode, the comparator 65 may compare a voltage level of the measurement line ML, which may be affected by an IDDQ current due to a bit line leakage current, with a reference voltage VREF level. For example, if the measurement line ML is at a lower voltage level than the reference voltage VREF, the comparator 65 may output a logic low output signal to the measurement pad 64. If the measurement pad 64 is at a logic low level, a defect caused by the bit line leakage current may be detected. Alternatively, if the measurement line ML is at a higher level than the reference voltage VREF, the comparator 65 may output a logic high output signal to the measurement pad 64. If the measurement pad 64 is at a logic high level, a defect caused by the bit line leakage current may not be detected.

According to example embodiments, a leakage current of a plurality of bit lines may be measured using a bit line leakage current measurement unit included in a memory device, thereby reducing test cost and improving a defect detection rate of the memory device.

Although example embodiments have been shown and described in this specification and figures, it would be appreciated by those skilled in the art that changes may be made to the illustrated and/or described example embodiments without departing from their principles and spirit.

What is claimed is:

1. A memory device comprising:
a plurality of bit line pairs;
at least one local data line pair connected to the bit line pairs in response to a column selection signal; and
a bit line leakage current measurement unit configured to monitor a direct drain quiescent current (IDDQ) flowing though at least one measurement line connected to the at least one local data line pair in response to a test mode signal.

2. The device of claim 1, wherein the bit line leakage current measurement unit comprises:
a first switch configured to connect the at least one local data line pair with a first measurement line, the at least one measurement line including the first measurement line and a second measurement line;
a second switch configured to connect the first measurement line with the second measurement line in response to the test mode signal;
a resistor connected between a power supply voltage and the second measurement line; and
a measurement pad connected to the second measurement line.

3. The device of claim 2, wherein the first switch comprises:
a first PMOS transistor connected between a local data line of the at least one local data line pair and the first measurement line, the first PMOS transistor having a gate connected to a ground voltage; and
a second PMOS transistor connected between a complementary local data line of the at least one local data line pair and the first measurement line, the second PMOS transistor having a gate connected to the ground voltage.

4. The device of claim 2, wherein the resistor is mounted outside the memory device.

5. The device of claim 1, wherein the bit line leakage current measurement unit comprises:
a first switch configured to connect the at least one local data line pair with a first measurement line, the at least one measurement line including the first measurement line and a second measurement line;
a second switch configured to connect the first measurement line with the second measurement line in response to the test mode signal;
a resistor connected between a power supply voltage and the second measurement line;
a comparator configured to compare a voltage level of the second measurement line with a reference voltage level; and
a measurement pad connected to an output terminal of the comparator.

6. The device of claim 5, wherein the first switch comprises:
a first PMOS transistor connected between a local data line of the at least one local data line pair and the first measurement line, the first PMOS transistor having a gate connected to a ground voltage; and
a second PMOS transistor connected between a complementary local data line of the at least one local data line pair and the first measurement line, the second PMOS transistor having a gate connected to the ground voltage.

7. The device of claim 5, wherein the resistor is mounted outside the memory device.

8. The device of claim 1, further comprising:
at least two load transistors configured to supply current to the at least one local data line pair in response to the test mode signal.

9. The device of claim 8, wherein the bit line leakage current measurement unit comprises:
a switch configured to connect the at least one local data line pair with the measurement line in response to the test mode signal;
a resistor connected between a power supply voltage and the measurement line; and
a measurement pad connected to the measurement line.

10. The device of claim 9, wherein the switch comprises:
a first PMOS transistor connected between a local data line of the at least one local data line pair and the measurement line, the first PMOS transistor having a gate configured to receive the test mode signal; and
a second PMOS transistor connected between a complementary data line of the at least one local data line pair and the measurement line, the second PMOS transistor having a gate configured to receive the test mode signal.

11. The device of claim 9, wherein the resistor is mounted outside the memory device.

12. The device of claim 8, wherein the bit line leakage current measurement unit comprises:
a switch configured to connect the at least one local data line pair with the measurement line in response to the test mode signal;
a resistor connected between a power supply voltage and the measurement line;
a comparator configured to compare a voltage level of the measurement line with a reference voltage level; and
a measurement pad connected to an output terminal of the comparator.

13. The device of claim 12, wherein the switch comprises:
a first PMOS transistor connected between a local data line of the at least one local data line pair and the measurement line, the first PMOS transistor having a gate configured to receive the test mode signal; and
a second PMOS transistor connected between a complementary data line of the at least one local data line pair and the measurement line, the second PMOS transistor having a gate configured to receive the test mode signal.

14. The device of claim 12, wherein the resistor is mounted outside the memory device.

15. The device of claim 1, further comprising:
a pulse width adjustment circuit configured to adjust an enabling period of the column selection signal.

16. The device of claim 15, wherein the pulse width adjustment circuit increases the enabling period of the column selection signal in response to the test mode signal.

17. A method comprising:
connecting at least one local data line pair to a plurality of bit line pairs in response to a column selection signal;
monitoring a direct drain quiescent current (IDDQ) flowing through a measurement line connected to the at least one local data line pair in response to a test mode signal.
